(19) United States
(12) Patent Application Publication
(10) Pub. No.: US 2024/0425407 A1
(43) Pub. Date: Dec. 26, 2024

(54) GLASS BLOCK, METHOD FOR PRODUCING SAME, AND PLASMA-RESISTANT MEMBER

(71) Applicant: AGC Inc., Tokyo (JP)

(72) Inventors: Shuhei OGAWA, Tokyo (JP); Tomonori OGAWA, Tokyo (JP); Kazuki KANEHARA, Tokyo (JP)

(73) Assignee: AGC Inc., Tokyo (JP)

(21) Appl. No.: 18/825,001

(22) Filed: Sep. 5, 2024

Related U.S. Application Data
(63) Continuation of application No. PCT/JP2023/010756, filed on Mar. 17, 2023.

(30) Foreign Application Priority Data
Mar. 31, 2022 (JP) 2022-060326

(51) Int. Cl. C03C 4/20; C03B 19/02; C03B 25/02; C03C 3/087; C03C 3/091; C03C 3/093; C03C 3/112; C03C 3/118; H01J 37/32

(52) U.S. Cl. CPC C03C 4/20; C03B 19/02; C03B 25/02; C03C 3/087; C03C 3/091; C03C 3/093; C03C 3/112; C03C 3/118; H01J 37/32477; C03C 2204/00; H01J 2237/334

(57) ABSTRACT

A glass block for a plasma resistant member, including silicon and at least one of magnesium and calcium, in which, in terms of mole percentage based on an oxide, a total content of MgO and CaO is 3.0 mol % or more and less than 29.0 mol %, a content of R²O is 3.0 mol % or more and less than 35.0 mol %, and a content of R¹₂O is 8.0 mol % or less, provided that R¹ is an alkali metal element and R² is an alkaline earth metal element.

### TECHNICAL FIELD

The present invention relates to a glass block, a method for manufacturing the same, and a plasma resistant member.

### BACKGROUND ART

A member used in a semiconductor manufacturing apparatus is often exposed to plasma and gradually worn during operation of the semiconductor manufacturing apparatus. The member which has been worn is replaced with a new member.

In recent years, as a product manufactured by the semiconductor manufacturing apparatus has become taller and more complex, a plasma environment to which the member is exposed become more severe, and in this case, it is frequently necessary to replace the member.

However, during the replacement of the member, the semiconductor manufacturing apparatus cannot be operated. Therefore, when replacement frequency of the member increases, production efficiency of the product decreases.

Therefore, the member used in the semiconductor manufacturing apparatus is required to have a longer lifespan. That is, good plasma resistance is required.

Examples of the semiconductor manufacturing apparatus include a plasma etching apparatus.

In the plasma etching apparatus, members such as a top plate (conductor type), a microwave introduction tube, a lift pin, various nozzles, an edge ring, an electrostatic chuck, a shower plate, and a protective cover for a sensor inside a chamber are mounted.

In the related art, materials such as a cordierite-based sintered body is used as the members (Patent Literature 1).

### CITATION LIST

### Patent Literature

Patent Literature 1: JPH09-295863A

### SUMMARY OF INVENTION

### Technical Problem

A material used as a plasma resistant member such as a window material (member for observing an inside of an apparatus from an outside) of the semiconductor manufacturing apparatus is required to have good plasma resistance and good mechanical strength.

The present invention has been made in view of the above points, and an object thereof is to provide a material excellent in plasma resistance and mechanical strength.

### Solution to Problem

As a result of intensive studies, the present inventors have found that the above object can be achieved by adopting the following configuration, and have completed the present invention.

That is, the inventors have found that the above problems can be solved by the following configurations.

[1] A glass block for a plasma resistant member, including silicon and at least one of magnesium and calcium,
in which, in terms of mole percentage based on an oxide,
a total content of MgO and CaO is 3.0 mol % or more and less than 29.0 mol %,
a content of R²O is 3.0 mol % or more and less than 35.0 mol %, and
a content of R¹₂O is 8.0 mol % or less, provided that R¹ is an alkali metal element and R² is an alkaline earth metal element.

[2] The glass block according to the [1], in which
a content of SiO₂ is 40.0 mol % or more and less than 90.0 mol %, and
a content of B₂O₃ is less than 30.0 mol %.

[3] The glass block according to the [1], in which
a ratio of a content of SrO to the total content of MgO and CaO is less than 0.50, and
the content of SrO is less than 15.0 mol %.

[4] The glass block according to the [1], in which
a ratio of a total content of BaO and SrO to the total content of MgO and CaO is less than 0.45.

[5 ] The glass block according to the [1], in which
a ratio of a content of BaO to the total content of MgO and CaO is less than 0.35.

[6 ] The glass block according to the [1], having an average thermal expansion coefficient at 50° C. to 350° C. of 5.0 ppm/° C. or less.

[7] The glass block according to the [1], in which
a ratio of a content of Al₂O₃ to the content of R²O is less than 0.6, and
the content of Al₂O₃ is less than 20.0 mol %.

[8] The glass block according to the [1], in which
a content of fluorine is 5.0 mass % or less with respect to a total mass of the glass block.

[9] The glass block according to the [1], having a visible light transmittance of 60% or more.

[10] The glass block according to the [1], in which
a ratio of a content of MgO to the total content of MgO and CaO is 0.1 to 0.9.

[11 ] The glass block according to the [1], in which
a content of P₂O₅ is 0.1 mol % or more and less than 5.5 mol %.

[12] The glass block according to the [1], in which
the content of R²O is 3.0 mol % or more and less than 20.0 mol %.

[13] A method for manufacturing the glass block according to any one of the [1] to [12], the method including:
melting a glass raw material by heating at 1650° C. or less; and
molding and annealing an obtained molten glass.

[14] A plasma resistant member including the glass block according to any one of the [1] to [12].

[15 ] The plasma resistant member according to the [14], in which
the plasma resistant member is to be mounted on a plasma etching apparatus, and is a window material, a top plate, a microwave introduction tube, a lift pin, a nozzle, an edge ring, an electrostatic chuck, a shower plate, or a protective cover for a sensor inside a chamber.

### Advantageous Effects of Invention

According to the present invention, a material excellent in plasma resistance and mechanical strength can be provided.

### DESCRIPTION OF EMBODIMENTS

The terms used in the present invention have the following meanings.

A numerical range represented using “to” means a range including numerical values described before and after “to” as a lower limit value and an upper limit value.

### [Glass Block]

A glass block according to the present invention is a glass block for a plasma resistant member, the glass block contains silicon and at least one of magnesium and calcium, and when an alkali metal element is R¹ and an alkaline earth metal element is R², a total content of MgO and CaO is 3.0 mol % or more and less than 29.0 mol %, a content of R²O is 3.0 mol % or more and less than 35.0 mol %, and a content of R¹₂O is 8.0 mol % or less in terms of mole percentage based on an oxide.

Hereinafter, the glass block is simply referred to as “glass”, and the glass block according to the present invention is also referred to as the “present glass block” or the “present glass”.

The present glass block is excellent in plasma resistance. This is presumed to be because by adopting the above configuration, a rate of deterioration due to plasma irradiation is reduced.

Further, the present glass block has excellent mechanical strength. This is presumed to be because, by adopting the above configuration, a content of an alkaline earth metal component that destabilizes a bonding state of the glass is not too large, and it is possible to sufficiently contain a network former component such as SiO₂ and Al₂O₃ that stabilizes the bonding state of the glass.

In the semiconductor manufacturing apparatus, an example of a member in the related art which is used in an environment exposed to plasma also includes a member made of sapphire.

However, sapphire is a material that is difficult to be processed and has poor mechanical strength, and is therefore very expensive. Since sapphire is manufactured by a single crystal growth method, the manufacturing characteristics are inferior, and there is a limit to a size that can be manufactured.

On the other hand, the present glass block has the excellent mechanical strength as compared with sapphire, and is easy to be processed, and therefore is a low cost. Since the present glass block can be easily manufactured by a manufacturing method to be described later, the present glass block has good manufacturing characteristics and can be appropriately changed in size.

Hereinafter, the present glass block will be described in detail.

First, a composition (glass composition) of the present glass block will be described below. That is, contents of elements that may be contained in the present glass block (expressed in terms of mole percentage based on an oxide) will be described.

### <Si, B, and P>

The present glass block includes silicon (Si).

The present glass block may further include boron (B), and phosphorus (P).

### <<SiO₂>>

For the reason that transparency of the present glass block is superior, a content of SiO₂ is preferably 40.0 mol % or more, more preferably 50.0 mol % or more, still more preferably 55.0 mol % or more, yet still more preferably 60.0 mol % or more, particularly preferably 62.0 mol % or more, and most preferably 64.0 mol % or more.

For the reason that plasma resistance and transparency of the present glass block are superior, the content of SiO₂ is preferably less than 90.0 mol %, more preferably less than 80.0 mol %, still more preferably less than 75.0 mol %, and particularly preferably less than 70.0 mol %. That is, the content of SiO₂ is preferably 40.0 mol % or more and less than 90.0 mol %.

<<B₂O₃>>

For the reason that the present glass block has excellent plasma resistance, a content of B₂O₃ is preferably less than 40.0 mol %, more preferably less than 30.0 mol %, still more preferably less than 15.0 mol %, yet still more preferably less than 12.0 mol %, particularly preferably less than 9.0 mol %, more particularly preferably less than 7.0 mol %, even still more preferably less than 5.0 mol %, and most preferably less than 3.0 mol %.

A lower limit of the content of B₂O₃ may be zero. For the reason that the present glass block has excellent manufacturing characteristics, the content of B₂O₃ is preferably 0.5 mol % or more, more preferably 1.0 mol % or more, still more preferably 1.5 mol % or more, particularly preferably 2.0 mol % or more, and most preferably 2.5 mol % or more. That is, the content of B₂O₃ may be 0 mol % or more and less than 40.0 mol %.

<<P₂O₅>>

For the reason that the present glass block has excellent plasma resistance, a content of P₂O₅ is preferably less than 5.5 mol %, more preferably 4.0 mol % or less, still more preferably 2.0 mol % or less, and particularly preferably 1.0 mol % or less.

A lower limit of the content of P₂O₅ may be zero. For the reason that the present glass block has a decreased devitrification temperature, the content of P₂o₅ is preferably 0.1 mol % or more, more preferably 0.3 mol % or more, and still more preferably 0.6 mol % or more. That is, the content of P₂O₅ may be 0 mol % or more and less than 5.5 mol %.

<<a: Total Content of SiO₂, B₂O₃, and P₂O₅>>

For the reason that the present glass block has excellent mechanical strength and transparency, a total content (a) of SiO₂, B₂O₃, and P₂O₅ is preferably 40.0 mol % or more, more preferably 50.0 mol % or more, still more preferably 60.0 mol % or more, particularly preferably 65.0 mol % or more, and most preferably 70.0 mol % or more.

For the reason that the present glass block has excellent plasma resistance, the total content (a) of SiO₂, B₂O₃, and P₂O₅ is preferably less than 95.0 mol %, more preferably less than 90.0 mol %, still more preferably less than 85.0 mol %, particularly preferably less than 80.0 mol %, and most preferably less than 75.0 mol %. That is, the total content (a) of SiO₂, B₂O₃, and P₂O₅ is preferably 40.0 mol % or more and less than 95.0 mol %.

### <Al, Ga, and In>

The present glass block may contain aluminum (Al), gallium (Ga), and indium (In).

<<Al₂O₃>>

For the reason that the present glass block has excellent plasma resistance, a content of Al₂O₃ is preferably less than 20.0 mol %, more preferably less than 18.0 mol %, still more preferably less than 16.0 mol %, yet still more preferably less than 14.0 mol %, particularly preferably less than 12.0 mol %, even still more preferably less than 10.0 mol %, and most preferably less than 8.0 mol %.

A lower limit of the content of Al₂O₃ may be zero. For the reason that the present glass block has excellent manufacturing characteristics, the content of Al₂O₃ is preferably more than 3.0 mol %, more preferably more than 5.0 mol %, and still more preferably more than 7.0 mol %. That is, the content of Al₂O₃ may be 0 mol % or more and less than 20.0 mol %.

<<Ga₂O₃>>

For the reason that the present glass block has excellent plasma resistance and transparency, a content of Ga₂O₃ is preferably 3.0 mol % or less, more preferably 1.0 mol % or less, and still more preferably 0.5 mol % or less.

A lower limit of the content of Ga₂O₃ is preferably zero. That is, the content of Ga₂O₃ is preferably 0 mol % or more and 3.0 mol % or less.

<<In₂O₃>>

For the reason that the present glass block has more excellent plasma resistance and transparency, a content of In₂O₃ is preferably 5.0 mol % or less, more preferably 3.0 mol % or less, and still more preferably 1.0 mol % or less.

A lower limit of the content of In₂O₃ is preferably zero. That is, the content of In₂O₃ is preferably 0 mol % or more and 5.0 mol % or less.

### <R²>

The present glass block may contain the alkaline earth metal element (R²).

Examples of the alkaline earth metal element (R²) include beryllium (Be), magnesium (Mg), calcium (Ca), strontium (Sr), barium (Ba), and radium (Ra).

However, the present glass block includes at least one of Mg and Ca as an essential element.

### <<R²O>>

For the reason that the present glass block has excellent plasma resistance, a content of R²O is 3.0 mol % or more, preferably 5.0 mol % or more, more preferably 10.0 mol % or more, and still more preferably 15.0 mol % or more.

On the other hand, for the reason that the present glass block has more excellent mechanical strength and transparency, the content of R²O is less than 35.0 mol %, preferably less than 33.0 mol %, more preferably less than 31.0 mol %, still more preferably less than 29.0 mol %, particularly preferably less than 27.0 mol %, and most preferably less than 20.0 mol %. That is, the content of R²O is 3.0 mol % or more and less than 35.0 mol %.

### <<MgO>>

For the reason that the present glass block has excellent mechanical strength and transparency, a content of MgO is preferably less than 20.0 mol %, more preferably less than 15.0 mol %, still more preferably less than 13.0 mol %, and particularly preferably less than 11.0 mol %.

For the reason that the present glass block has excellent plasma resistance, the content of MgO is preferably 2.0 mol % or more, more preferably 4.0 mol % or more, still more preferably 6.0 mol % or more, and particularly preferably 8.0 mol % or more. That is, the content of MgO is preferably 2.0 mol % or more and less than 20.0 mol %.

### <<CaO>>

For the reason that the present glass block has more excellent plasma resistance, a content of CaO is preferably 5.0 mol % or more, more preferably 10.0 mol % or more, still more preferably 15.0 mol % or more, and particularly preferably 18.0 mol % or more.

On the other hand, for the reason that the present glass block has more excellent plasma resistance, mechanical strength, and transparency, a content of CaO is preferably less than 25.0 mol %, more preferably less than 23.0 mol %, still more preferably less than 21.0 mol %, and particularly preferably less than 19.0 mol %. That is, the content of CaO is preferably 5.0 mol % or more and less than 25.0 mol %.

### <<Total Content of MgO and CaO>>

For the reason that the present glass block has more excellent plasma resistance, a total content of MgO and CaO is 3.0 mol % or more, preferably 9.0 mol % or more, more preferably 13.0 mol % or more, still more preferably 17.0 mol % or more, and particularly preferably 20.0 mol % or more.

On the other hand, for the reason that the present glass block has more excellent mechanical strength and transparency, the total content of MgO and CaO is less than 29.0 mol %, preferably less than 27.0 mol %, more preferably less than 25.0 mol %, still more preferably less than 23.0 mol %, and particularly preferably less than 21.0 mol %. That is, the total content of MgO and CaO is 3.0 mol % or more and less than 29.0 mol %.

### <<Ratio of (MgO/(MgO+CaO))>>

For the reason that the present glass block has excellent plasma resistance, a ratio of the content of MgO (unit: mol %) to the total content of MgO and CaO (unit: mol %) (MgO/(MgO+CaO)) is preferably 0.1 to 0.9, more preferably 0.14 to 0.5, still more preferably 0.17 to 0.4, particularly preferably 0.2 to 0.35, and most preferably 0.23 to 0.30.

Here, MgO/(MgO+CaO) is preferably 0.1 or more, more preferably 0.14 or more, still more preferably 0.17 or more, still more preferably 0.2 or more, and particularly preferably 0.23 or more. Further, MgO/(MgO+CaO) is preferably 0.9 or less, more preferably 0.5 or less, still more preferably 0.4 or less, yet still more preferably 0.35 or less, and particularly preferably 0.30 or less.

### <<Ratio of (CaO/SiO₂)>>

For the reason that the present glass block has excellent plasma resistance, a ratio of the content of CaO (unit: mol %) to the total content of SiO₂ (unit: mol %) (CaO/SiO₂) is preferably 0.1 to 0.9, more preferably 0.14 to 0.5, still more preferably 0.17 to 0.4, particularly preferably 0.2 to 0.35, and most preferably 0.23 to 0.30.

Here, CaO/SiO₂ is preferably 0.1 or more, more preferably 0.14 or more, still more preferably 0.17 or more, yet still more preferably 0.2 or more, and particularly preferably 0.23 or more. Further, CaO/SiO₂ is preferably 0.9 or less, more preferably 0.5 or less, still more preferably 0.4 or less, yet still more preferably 0.35 or less, and particularly preferably 0.30 or less.

### <<SrO>>

For the reason that the present glass block has excellent plasma resistance, a content of SrO is preferably less than 15.0 mol %, more preferably less than 10.0 mol %, still more preferably less than 5.0 mol %, yet still more preferably less than 4.0 mol %, particularly preferably less than 3.0 mol %, even still more preferably less than 2.0 mol %, and most preferably less than 1.0 mol %.

A lower limit of the content of SrO is preferably zero. That is, a total content of SrO is preferably 0 mol % or more and less than 15.0 mol %.

### <<Ratio of (SrO/(MgO+CaO))>>

For the reason that the present glass block has excellent plasma resistance, a ratio of the content of SrO (unit: mol %) to the total content of MgO and CaO (unit: mol %) (SrO/(MgO+CaO)) is preferably less than 0.50, more preferably less than 0.30, still more preferably less than 0.20, and particularly preferably less than 0.10.

A lower limit of the ratio of (SrO/(MgO+CaO)) is preferably zero. That is, the ratio of (SrO/(MgO+CaO)) is preferably 0 or more and less than 0.50.

### <<BaO>>

For the reason that the present glass block has more excellent plasma resistance, a content of BaO is preferably less than 15.0 mol %, more preferably less than 10.0 mol %, still more preferably less than 5.0 mol %, yet still more preferably less than 4.0 mol %, particularly preferably less than 3.0 mol %, even still more preferably less than 2.0 mol %, and most preferably less than 1.0 mol %.

A lower limit of the content of BaO is preferably zero. The content of BaO is preferably 0 mol % or more and less than 15.0 mol %.

### <<Ratio of (BaO/(MgO+CaO))>>

For the reason that the present glass block has excellent plasma resistance, a ratio of the content of BaO (unit: mol %) to the total content of MgO and CaO (unit: mol %) (BaO/(MgO+CaO)) is preferably less than 0.35, more preferably less than 0.25, even more preferably less than 0.15, and particularly preferably less than 0.05.

A lower limit of the ratio of (BaO/(MgO+CaO)) is preferably zero. That is, the ratio of (BaO/(MgO+CaO)) is preferably 0 or more and less than 0.35.

### <<Ratio of ((BaO+SrO)/(MgO+CaO))>>

For the reason that the present glass block has excellent plasma resistance, a ratio of a total content of BaO and SrO (unit: mol %) to the total content of MgO and CaO (unit: mol %) ((BaO+SrO)/(MgO+CaO)) is preferably less than 0.75, more preferably less than 0.45, still more preferably less than 0.30, particularly preferably less than 0.15, and most preferably less than 0.10.

A lower limit of the ratio of ((BaO+SrO)/(MgO+CaO)) is preferably zero. That is, the ratio of ((BaO+SrO)/(MgO+CaO)) is preferably 0 or more and less than 0.75.

<<Ratio of (Al₂O₃/R²O)>>

For the reason that the present glass block has excellent plasma resistance, a ratio of a content of Al₂O₃ (unit: mol %) to a content of R²O (unit: mol %) (Al₂O₃/R²O) is preferably less than 1.8, more preferably less than 1.0, still more preferably less than 0.6, yet still more preferably less than 0.5, particularly preferably less than 0.4, and most preferably less than 0.3. A lower limit of the ratio of (Al₂O₃/R²O) may be zero. For the reason that the present glass block has more excellent manufacturing characteristics, the ratio of (Al₂O₃/R²O) is preferably more than 0.1, more preferably more than 0.2, and still more preferably more than 0.25. That is, the ratio of (Al₂O₃/R²O) is preferably 0 or more and less than 1.8.

### <Y>

The present glass block may contain yttrium (Y).

A content of Y₂O₃ in the present glass block is preferably 5.0 mol % or less, more preferably 3.0 mol % or less, and still more preferably 1.0 mol % or less.

A lower limit of the total content of Y₂O₃ may be zero. For the reason that the present glass block has excellent plasma resistance, the content is preferably 0.4 mol % or more, and more preferably 0.8 mol % or more. That is, the content of Y₂O₃ may be 0 mol % or more and 5.0 mol % or less.

### <R¹>

The present glass block may contain the alkali metal element (R¹).

Examples of the alkali metal element (R¹) include lithium (Li), sodium (Na), potassium (K), rubidium (Rb), cesium (Cs), and francium (Fr). Among these, substantially, lithium (Li), sodium (Na), and potassium (K) are preferable.

<<R¹₂O>>

For the reason that the present glass block has excellent plasma resistance, a content of R¹₂O is 8.0 mol % or less, preferably 4.0 mol % or less, more preferably 1.2 mol % or less, still more preferably 0.8 mol % or less, yet still more preferably 0.4 mol % or less, particularly preferably 0.1 mol % or less, and most preferably 0.01 mol % or less. A lower limit of the content of R¹₂O is preferably zero. That is, the content of R¹₂O is, for example, 0 mol % or more and 8.0 mol % or less.

### <Zn and Zr>

The present glass block may contain zinc (Zn) and zirconium (Zr).

### <<ZnO>>

For the reason that the present glass block has excellent plasma resistance and mechanical strength, a content of ZnO is preferably 7.0 mol % or less, more preferably 4.0 mol % or less, still more preferably 1.0 mol % or less, and particularly preferably 0.5 mol % or less.

A lower limit of the content of ZnO is preferably zero. That is, the content of ZnO is preferably 0 mol % or more and 7.0 mol % or less.

### <<ZrO₂>>

For the reason that the present glass block has excellent plasma resistance, a content of ZrO₂ is preferably 6.0 mol % or less, more preferably 2.5 mol % or less, still more preferably 1.0 mol % or less, and particularly preferably 0.5 mol % or less.

A lower limit of the content of ZrO₂ is preferably zero. That is, the content of ZrO₂ is preferably 0 mol % or more and 6.0 mol % or less.

### <Impurity Element>

For the reason that the present glass block has excellent plasma resistance, a content of an impurity element in terms of an oxide is preferably 15.0 mol % or less, more preferably 10.0 mol % or less, still more preferably 7.5 mol % or less, yet still more preferably 5.0 mol % or less, particularly preferably 1.0 mol % or less, even still more preferably 0.5 mol % or less, and most preferably 0.05 mol % or less.

A lower limit of the content of the impurity element in terms of an oxide is preferably zero.

The impurity element is a metal element excluding silicon (Si), boron (B), phosphorus (P), aluminum (Al), gallium (Ga), indium (In), an alkaline earth metal element (R²), yttrium (Y), an alkali metal element (R′), zirconium (Zr), and zinc (Zn).

Examples of the impurity element include Cu, Fe, Ni, Cr, Sn, Co, V, Bi, Se, Ce, Er, Nd, Ge, Ti, Mn, and Ta.
A content of Cu in terms of an oxide specifically means a content of CuO.
A content of Fe in terms of an oxide specifically means a content of Fe₂O₃.
A content of Ni in terms of an oxide specifically means a content of NiO.
A content of Cr in terms of an oxide specifically means a content of Cr₂O₃.
A content of Sn in terms of an oxide specifically means a content of SnO₂.
A content of Co in terms of an oxide specifically means a content of CO₃O₄.
A content of V in terms of an oxide specifically means a content of V₂O₅.
A content of Bi in terms of an oxide specifically means a content of Bi₂O₃.
A content of Se in terms of an oxide specifically means a content of SeO₂.
A content of Ce in terms of an oxide specifically means a content of CeO₂.
A content of Er in terms of an oxide specifically means a content of Er₂O₃.
A content of Nd in terms of an oxide specifically means a content of Nd₂O₃.
A content of Ge in terms of an oxide specifically means a content of GeO₂.
A content of Ti in terms of an oxide specifically means a content of TiO₂.
A content of Mn in terms of an oxide specifically means a content of MnO₂.
A content of Ta in terms of an oxide specifically means a content of Ta₂O₅.

### <F>

The present glass block may contain fluorine (F).

For the reason that the present glass block has excellent manufacturing characteristics, a content of F is preferably 5.0 mass % or less, more preferably 4.0 mass % or less, still more preferably 3.0 mass % or less, particularly preferably 2.0 mass % or less, and most preferably 1.0 mass % or less based on a total mass of the glass block.

A lower limit of the content of F may be zero. That is, the content of F may be 0 mass % or more and 5.0 mass % or less.

The content (expressed in mole percentage based on an oxide) of each of the above-mentioned elements (excluding Si) in the glass block is measured using an X-ray fluorescence device (XRF) (ZSX100e manufactured by Rigaku Corporation). That is, X-ray intensity of each element on a surface of the glass block is measured and quantitatively analyzed to thereby obtain the content of each element.

The content of SiO₂ in the glass block is determined as follows.

First, a powder sample is taken from a center of the glass block by grinding, and a total oxygen amount Z1 in the glass block is obtained by an infrared absorption method using an oxygen/hydrogen analyzer (ROH-600 manufactured by LECO Corporation).

An oxygen amount Z3 is calculated by subtracting an oxygen amount Z2 bound to the elements (excluding Si) contained in the glass block in the stoichiometric composition from the total oxygen amount Z1 in the glass block (oxygen amount Z3=total oxygen amount Z1−oxygen amount Z2).

Assuming that the entire oxygen amount Z3 has been used for bonding with silicon atoms, the oxygen amount Z3 is converted to an amount of SiO₂. The amount of SiO₂ obtained in this manner is set as the content of SiO₂ in the glass block.

### <Expansion Coefficient>

From the viewpoint of preventing cracking at the time of manufacturing the present glass block, an average thermal expansion coefficient (hereinafter, also simply referred to as “expansion coefficient”) of the present glass block at 50° C. to 350° C. is preferably 5.0 ppm/° C. or less, more preferably 4.5 ppm/° C. or less, still more preferably 4.0 ppm/° C. or less, yet still more preferably 3.5 ppm/° C. or less, particularly preferably 3.0 ppm/° C. or less, even still more preferably 2.5 ppm/° C. or less, and most preferably 2.0 ppm/° C. or less.

An expansion coefficient is measured using a differential thermal expansion meter in accordance with a method described in JIS R 3102-1995.

### <Visible Light Transmittance>

Visible light transmittance of the present glass block is preferably 60% or more, more preferably 70% or more, still more preferably 80% or more, yet still more preferably 85% or more, particularly preferably 90% or more, even still more preferably 93% or more, and most preferably 95% or more. An upper limit is preferably 100%.

The visible light transmittance is measured by the method in accordance with JIS R 3106 (1998).

In order to keep the visible light transmittance within the above range, it is preferable to set the content of each component as described above and to manufacture the glass block by a method (the present manufacturing method) to be described later.

### <Shape>

Examples of a shape of the present glass block include a plate shape (for example, a disc shape and a flat plate shape), a spherical shape, a spheroidal shape, and the like, and is appropriately selected according to an application.

The “glass block”, in any form, is at least a concept free of a glass frit, a glass powder, and a glass fiber.

When the present glass block has a plate shape, an area of at least one surface (for example, a main surface) of the present glass block is preferably 25 mm² or more, more preferably 100 mm² or more, still more preferably 500 mm² or more, yet still more preferably 1,000 mm² or more, particularly preferably 5,000 mm² or more, more particularly preferably 10,000 mm² or more, even still more preferably 40,000 mm² or more, and most preferably 90,000 mm² or more.

When the present glass block has the plate shape, a thickness of the present glass block (thickness of a thinnest portion) is preferably 0.3 mm or more, more preferably 0.5 mm or more, still more preferably 1 mm or more, yet still more preferably 3 mm or more, particularly preferably 6 mm or more, more particularly preferably 10 mm or more, even still more preferably 15 mm or more, and most preferably 20 mm or more.

On the other hand, for the reason that the crystallization of the present glass block is prevented and the transparency is more excellent, a thickness of the present glass block is preferably 500 mm or less, more preferably 100 mm or less, still more preferably 80 mm or less, yet still more preferably 60 mm or less, even still more preferably 50 mm or less, particularly preferably 40 mm or less, and most preferably 30 mm or less. That is, the thickness of the present glass block is preferably 0.3 mm or more and 500 mm or less.

For the reason that the present glass block is excellent in transparency, generation of heterogeneous phases (crystalline phase, colloidal metal, ceramic particles, and the like) is preferably prevented.

In a semiconductor manufacturing apparatus, a transparent member in the related art which is used in an environment exposed to plasma is, for example, a quartz member.

However, quartz has insufficient plasma resistance.

On the other hand, the present glass block has excellent plasma resistance and mechanical strength.

### Application

The present glass block can be suitably used as a plasma resistant member. However, the application of the present glass block is not limited thereto.

Examples of the plasma resistant member include a member mounted on a plasma etching apparatus. Examples of the member include a window material, a top plate, a microwave introduction tube, a lift pin, a nozzle, an edge ring, an electrostatic chuck, a shower plate, and a protective cover for a sensor inside a chamber.

### [Method for Manufacturing Glass Block]

Next, a method for manufacturing the present glass block (hereinafter, also referred to as the “present manufacturing method”) will be described. In the present manufacturing method, generally, glass raw materials are melted by heating, and the obtained molten glass is molded, followed by annealing.

More specifically, first, various glass raw materials are weighed and mixed such that compositions of the glass block to be obtained are the above-described glass compositions.

Next, the mixed glass raw materials are heated and melted using a glass melting furnace or the like. At this time, refining, homogenization, and the like are appropriately performed on the molten material by a known method. Thus, molten glass is obtained.

Thereafter, the obtained molten glass is molded into a desired shape, followed by annealing. A molding method is not particularly limited, and examples thereof include a float method, a press method, a fusion method, and a down-draw method. After the obtained molten glass is molded into a temporary shape and then annealed, the obtained temporary shaped body may be subjected to processing such as cutting. Thus, a glass block having a desired shape is obtained.

If necessary, processing such as grinding and polishing may be performed on the obtained glass block.

A temperature (hereinafter, also referred to as “melting temperature”) at which the glass raw materials are heated and melted is preferably 1650° C. or lower, more preferably 1600° C. or lower, and still more preferably 1550° C. or lower, for the reason that manufacturing characteristics are excellent.

### <Temperature T₂>

For the reason that the present glass block has more excellent manufacturing characteristics, a temperature T₂ (unit: ° C.) at which viscosity of the present glass block becomes log η=2 is preferably 1735° C. or lower, more preferably 1690° C. or lower, still more preferably 1650° C. or lower, particularly preferably 1610° C. or lower, and most preferably 1570° C. or lower. A lower limit is preferably 1100° C.

The temperature T₂ at which the viscosity of the glass block becomes log η=2 is measured by the following method. An annealing point of the glass block is measured in accordance with JIS R3103-2, and a softening point is measured in accordance with JIS R3103-1. Next, a temperature at which the viscosity is 100 dPa·s to 10,000 dPa·s is measured by a rotation viscosimeter, and the measured temperature, together with the annealing point and the softening point, is fitted to a Fulcher formula to determine a temperature (unit: ° C.) at which viscosity η (unit: dPa·s) of a glass plate becomes log η=2.

A time (hereinafter also referred to as “melting time”) for heating and melting the glass raw materials is preferably 24 hours or less, more preferably 12 hours or less, still more preferably 10 hours or less, yet still more preferably 8 hours or less, particularly preferably 6 hours or less, and most preferably 4 hours or less, from the viewpoint of refining property.

A cooling rate for cooling the molten glass is preferably 0.5° C./min or more, more preferably 1° C./min or more, still more preferably 5° C./min or more, and particularly preferably 10° C./min or more from the viewpoint of crystal acceleration.

As described above, the following configurations are disclosed in the present description.

<1> A glass block for a plasma resistant member, including silicon and at least one of magnesium and calcium,
in which, in terms of mole percentage based on an oxide,
a total content of MgO and CaO is 3.0 mol % or more and less than 29.0 mol %,
a content of R²O is 3.0 mol % or more and less than 35.0 mol %, and
a content of R¹₂O is 8.0 mol % or less,
provided that R¹ is an alkali metal element and R² is an alkaline earth metal element.

<2> The glass block according to the <1>, in which
a content of SiO₂ is 40.0 mol % or more and less than 90.0 mol %, and
a content of B₂O₃ is less than 30.0 mol %.

<3> The glass block according to the <1> or <2>, in which
a ratio of a content of SrO to the total content of MgO and CaO is less than 0.50, and
the content of SrO is less than 15.0 mol %.

<4> The glass block according to any one of the <1> to <3>, in which
a ratio of a total content of BaO and SrO to the total content of MgO and CaO is less than 0.45.

<5> The glass block according to any one of the <1> to <4>, in which
a ratio of a content of BaO to the total content of MgO and CaO is less than 0.35.

<6> The glass block according to any one of the <1> to <5>, having an average thermal expansion coefficient at 50° C. to 350° C. of 5.0 ppm/° C. or less.

<7> The glass block according to any one of the <1> to <6>, in which
a ratio of a content of Al₂O₃ to the content of R²O is less than 0.6, and
the content of Al₂O₃ is less than 20.0 mol %.

<8> The glass block according to any one of the <1> to <7>, in which
a content of fluorine is 5.0 mass % or less with respect to a total mass of the glass block.

<9> The glass block according to any one of the <1> to <8>, having a visible light transmittance of 60% or more.

<10> The glass block according to any one of the <1> to <9>, in which
a ratio of a content of MgO to the total content of MgO and CaO is 0.1 to 0.9.

<11> The glass block according to any one of the <1> to <10>, in which
a content of P₂O₅ is 0.1 mol % or more and less than 5.5 mol %.

<12> The glass block according to any one of the <1> to <11>, in which
the content of R²O is 3.0 mol % or more and less than 20.0 mol %.

<13> A method for manufacturing the glass block according to any one of the <1> to <12>, the method including:
melting a glass raw material by heating at 1650° C. or less; and
molding and annealing an obtained molten glass.

<14> A plasma resistant member including the glass block according to any one of the <1> to <12>.

<15> The plasma resistant member according to the <14>, in which
the plasma resistant member is to be mounted on a plasma etching apparatus, and is a window material, a top plate, a microwave introduction tube, a lift pin, a nozzle, an edge ring, an electrostatic chuck, a shower plate, or a protective cover for a sensor inside a chamber.

### EXAMPLES

Hereinafter, the present invention will be specifically described with reference to Examples. However, the present invention is not limited to Examples described below.

Hereinafter, Examples 1 to 35 are Working Examples, and Examples 36 to 41 are Comparative Examples.

### Example 1 to Example 41

A glass block in each of Examples was obtained as follows.

Glass raw materials were weighed and mixed such that the glass blocks to be obtained contained compositions (expressed in terms of mole percentage based on oxides) shown in the following Tables 1 to 5 and were 400 g.

The mixed glass raw materials were placed in a platinum crucible, placed in an electric furnace, and heated at a temperature of 1500° C. to 1700° C. for about 3 hours to melt, followed by refining and homogenization to thereby obtain molten glass.

A part of the obtained molten glass was poured into a metal mold, held at a temperature approximately 50° C. higher than a glass transition point for 1 hour, and cooled to room temperature at a rate of 0.5° C./min to thereby obtain a sheet-shaped glass block (area of main surface: 10,000 mm² and thickness: 10 mm).

However, in Examples 38 and 41, commercially available quartz and silicon blocks were used, respectively, instead of the glass block.

Hereinafter, for convenience, the blocks in Examples 38 and 41 are also referred to as “glass blocks”.

### <Content of Each Element>

In the glass block in each of Examples, a content of each element (expressed in terms of mole percentage based on oxides) was obtained by the method described above. Results are shown in the following Tables 1 to 5.

In Example 34, Cu among the impurity elements was measured. That is, in Example 34, a numerical value described in the “impurity element (in terms of an oxide)” column in the table indicate a content of CuO.

In Example 41 (silicon), a content of Si is expressed as 100 mol % for convenience.

### <Expansion Coefficient>

An expansion coefficient of the glass block in each of Examples was obtained by the method described above. Results are shown in the following Tables 1 to 5.

### <Visible Light Transmittance>

Visible light transmittance of the glass block in each of Examples was obtained by the method described above. Results are shown in the following Tables 1 to 5.

In a “visible light transmittance” column in each of Tables 1 to 5, “90% or more” means visible light transmittance of 90% to 100%, “80% or more” means visible light transmittance of 80% or more and less than 90%, “70% or more” means visible light transmittance of 70% or more and less than 80%, “60% or more” means visible light transmittance of 60% or more and less than 70%, and “less than 60%” means visible light transmittance of 0% or more and less than 60%. The visible light transmittance was measured using a test piece having a size of 20 mm×20 mm×2 mm cut out from the glass block. The test piece was formed by mirror-finishing a surface of 20 mm×20 mm.

### <Temperature T₂>

For the glass block in each of Examples, the temperature T₂ (unit: ° C.) at which the viscosity is log η=2 was obtained by the above-described method. Results are shown in the following Tables 1 to 5.

As the T₂ is lower, the manufacturing characteristics can be evaluated as more excellent. Specifically, when T₂ were 1735° C. or less, it was evaluated that the manufacturing characteristics were excellent. For the reason that the manufacturing characteristics are more excellent, T₂ is more preferably 1690° C. or lower, still more preferably 1650° C. or lower, particularly preferably 1610° C. or lower, and most preferably 1570° C. or lower

### <Manufacturing Characteristics>

The glass block in each of Examples was evaluated for manufacturing characteristics.

The glass block was evaluated based on the occurrence of three types of defects (bubbles, cracks, and opaque crystals). A block was observed from a main surface, when the number of bubbles of 0.1 mm² or more was 3 or less, the number of cracks of 1.0 mm or more was 1 or less, and a total area ratio of crystals of 0.1 mm² or more was less than 0.1%, the block was marked as “A”. In a case in which one or more of the three types of defects does not fall within these criteria, when the number of bubbles of 0.1 mm² or more was 4 or more and 5 or less, the number of cracks of 1.0 mm or more was 2 or more and 3 or less, or a total area ratio of crystals of 0.1 mm² or more was 0.1% or more and less than 0.5%, the block was marked as “B”, and when the number of bubbles of 0.1 mm² or more was 6 or more, the number of cracks of 1.0 mm or more was 4 or more, or a total area ratio of crystals of 0.1 mm² or more is 0.5% or more, the block was marked as “C”.

If “A” or “B” was marked, manufacturing characteristics were evaluated to be excellent.

### <Etching Amount>

An etching amount was determined for the glass block in each of Examples, and plasma resistance was evaluated.

Specifically, a test piece having a size of 10 mm×5 mm×4 mm was cut out from the glass block, and a surface of 10 mm×5 mm was mirror-finished. A Kapton tape was applied as a mask to a part of the mirror-finished surface, and etching was performed with plasma gas. Thereafter, the etching amount was determined by measuring a difference between the etched portion and the non-etched portion by using a stylus surface profiler (Dectak 150, manufactured by ULVAC, Inc.).

As a plasma etching apparatus, EXAM (model: POEM, manufactured by SHINKO SEIKI CO., LTD.) was used. Etching was performed with CF₄ gas for 195 minutes under a pressure of 10 Pa and an output of 350 W in a RIE mode (reactive ion etching mode).

As the etching amount (unit: nm) is smaller, plasma resistance can be evaluated to be excellent.

Specifically, when the etching amount was 4,000 nm or less, the plasma resistance was evaluated to be excellent. For the reason that the plasma resistance is more excellent, the etching amount is preferably 1000 nm or less, more preferably 700 nm or less, still more preferably 500 nm or less, yet still more preferably 400 nm or less, and even still more preferably 350 nm or less.

### <Presence or Absence of Heterogeneous Phase>

The glass block in each of Examples was visually observed, and presence or absence of a heterogeneous phase (crystalline phase, colloidal metal, ceramic particles, or the like) was observed.

When there is no heterogeneous phase, “A” is marked in the following Tables 1 to 5, when there are heterogeneous phases and a total area of regions in which the heterogeneous phases are present is 10% or less of an area of a main surface of the glass block, “B” is marked, and when there are heterogeneous phases and a total area of regions in which the heterogeneous phases are present is more than 10% of an area of a main surface of the glass block, “C” is marked.

If “A” or “B” was marked, transparency was evaluated to be excellent. “A” is preferable for the reason that the transparency is more excellent.

### <Processability>

The glass block in each of Examples was evaluated for processability.

Specifically, ten test pieces each having a size of 10 mm×5 mm×4 mm were cut out from the glass block. The prepared test pieces were visually observed to check presence or absence of damage such as cracks, scratches, and breaks.

When none of the 10 test pieces had any damage, “A” was marked in the following Tables 1 to 5, when only one test piece had damage, “B” was marked, and when two or more test pieces had damage, “C” was marked.

If “A” or “B” was marked, mechanical strength was evaluated to be excellent. “A” is preferable for the reason that the mechanical strength is more excellent.

TABLE 1

| | | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|---|
| SiO₂ | Mol % | 61.8 | 64.0 | 66.5 | 66.5 | 66.8 | 63.0 | 61.6 | 63.3 | 66.0 |
| B₂O₃ | Mol % | 30.0 | 4.0 | 10.0 | 7.8 | 4.6 | 0.0 | 0.0 | 0.0 | 0.0 |
| P₂O₅ | Mol % | 0.0 | 0.0 | 0.0 | 0.0 | 0.0 | 0.0 | 0.0 | 0.0 | 0.0 |
| a (SiO₂ + B₂O₃ + P₂O₅) | Mol % | 91.8 | 68.0 | 76.5 | 74.3 | 71.4 | 63.0 | 61.6 | 63.3 | 66.0 |
| Al₂O₃ | Mol % | 4.0 | 16.0 | 12.0 | 12.5 | 13.0 | 8.5 | 12.1 | 8.5 | 7.0 |
| Ga₂O₃ | Mol % | 0.0 | 0.0 | 0.0 | 0.0 | 0.0 | 0.0 | 0.0 | 0.0 | 0.0 |
| MgO | Mol % | 3.2 | 6.5 | 6.5 | 7.3 | 8.0 | 12.0 | 15.3 | 13.6 | 8.0 |
| CaO | Mol % | 0.0 | 2.5 | 4.2 | 5.1 | 6.6 | 8.0 | 11.0 | 9.0 | 6.6 |
| SrO | Mol % | 0.8 | 1.0 | 0.8 | 0.8 | 1.0 | 5.0 | 0.0 | 2.1 | 7.1 |
| BaO | Mol % | 0.2 | 0.0 | 0.0 | 0.0 | 0.0 | 2.0 | 0.0 | 2.0 | 3.3 |
| MgO + CaO | Mol % | 3.2 | 9.0 | 10.7 | 12.4 | 14.6 | 20.0 | 26.3 | 22.6 | 14.6 |
| R₂O (MgO + CaO + SrO + BaO) | Mol % | 4.2 | 10.0 | 11.5 | 13.2 | 15.6 | 27.0 | 26.3 | 26.7 | 25.0 |
| MgO/(CaO + MgO) | — | 1.00 | 0.72 | 0.61 | 0.59 | 0.55 | 0.60 | 0.58 | 0.60 | 0.55 |
| CaO/SiO₂ | — | 0.00 | 0.04 | 0.06 | 0.08 | 0.10 | 0.13 | 0.18 | 0.14 | 0.10 |
| SrO/(MgO + CaO) | — | 0.25 | 0.11 | 0.07 | 0.06 | 0.07 | 0.25 | 0.00 | 0.09 | 0.49 |
| BaO/(MgO + CaO) | — | 0.06 | 0.00 | 0.00 | 0.00 | 0.00 | 0.10 | 0.00 | 0.09 | 0.23 |
| (BaO + SrO)/(MgO + CaO) | — | 0.31 | 0.11 | 0.07 | 0.06 | 0.07 | 0.35 | 0.00 | 0.18 | 0.71 |
| Al₂O₃/R²O | — | 0.95 | 1.60 | 1.04 | 0.95 | 0.83 | 0.31 | 0.46 | 0.32 | 0.28 |
| Y₂O₃ | Mol % | 0.0 | 0.0 | 0.0 | 0.0 | 0.0 | 0.0 | 0.0 | 0.0 | 0.0 |
| Li₂O | Mol % | 0.0 | 0.0 | 0.0 | 0.0 | 0.0 | 0.0 | 0.0 | 0.0 | 0.0 |
| Na₂O | Mol % | 0.0 | 0.0 | 0.0 | 0.0 | 0.0 | 1.0 | 0.0 | 1.0 | 0.4 |
| K₂O | Mol % | 0.0 | 0.0 | 0.0 | 0.0 | 0.0 | 0.3 | 0.0 | 0.3 | 0.1 |
| R¹₂O (Li₂O + Na₂O + K₂O) | Mol % | 0.0 | 0.0 | 0.0 | 0.0 | 0.0 | 1.3 | 0.0 | 1.3 | 0.5 |
| ZnO | Mol % | 0.0 | 6.0 | 0.0 | 0.0 | 0.0 | 0.0 | 0.0 | 0.0 | 0.0 |
| ZrO₂ | Mol % | 0.0 | 0.0 | 0.0 | 0.0 | 0.0 | 0.2 | 0.0 | 0.2 | 1.5 |
| Impurity element (in terms of oxide) | Mol % | 0.0 | 0.0 | 0.0 | 0.0 | 0.0 | 0.0 | 0.0 | 0.0 | 0.0 |
| Si | Mol % | 0.0 | 0.0 | 0.0 | 0.0 | 0.0 | 0.0 | 0.0 | 0.0 | 0.0 |
| F | Mass % | 0.0 | 0.0 | 0.0 | 0.0 | 0.0 | 0.15 | 0.0 | 0.15 | 0.15 |
| Expansion coefficient | ppm/° C. | 3.0 | 3.2 | 3.3 | 3.3 | 3.5 | 5.5 | 4.5 | 5.5 | 5.5 |
| Visible light transmittance | % | 90% or | 90% or | 90% or | 90% or | 90% or | 90% or | 90% or | 90% or | 90% or |
| | | more | more | more | more | more | more | more | more | more |
| T₂ (logη = 2) | ° C. | 1733 | 1584 | 1661 | 1655 | 1647 | 1569 | 1523 | 1578 | 1569 |
| Manufacturing characteristics | — | B | A | B | B | A | A | A | A | A |
| Etching amount | nm | 3255 | 1100 | 703 | 683 | 580 | 529 | 422 | 548 | 672 |
| Presence or absence of | — | A | A | A | A | A | A | A | A | A |
| heterogeneous phase | | | | | | | | | | |
| Processability | — | A | A | A | A | A | A | A | A | A |

TABLE 2

| | | Ex. 10 | Ex. 11 | Ex. 12 | Ex. 13 | Ex. 14 | Ex. 15 | Ex. 16 | Ex. 17 | Ex. 18 |
|---|---|---|---|---|---|---|---|---|---|---|
| SiO₂ | Mol % | 63.0 | 60.0 | 60.0 | 60.0 | 66.0 | 64.0 | 64.7 | 66.5 | 66.5 |
| B₂O₃ | Mol % | 0.0 | 0.0 | 3.0 | 0.0 | 7.8 | 0.0 | 0.0 | 10.0 | 10.0 |
| P₂O₅ | Mol % | 0.0 | 0.0 | 0.0 | 0.0 | 0.0 | 0.0 | 0.0 | 0.0 | 0.0 |
| a (SiO₂ + B₂O₃ + P₂O₅) | Mol % | 63.0 | 60.0 | 63.0 | 60.0 | 73.8 | 64.0 | 64.7 | 76.5 | 76.5 |
| Al₂O₃ | Mol % | 8.5 | 11.5 | 8.5 | 8.5 | 11.3 | 3.5 | 1.6 | 12.0 | 12.0 |
| Ga₂O₃ | Mol % | 0.0 | 0.0 | 0.0 | 0.0 | 0.0 | 0.0 | 0.0 | 0.0 | 0.0 |
| MgO | Mol % | 12.0 | 12.0 | 12.0 | 12.0 | 5.1 | 14.5 | 15.1 | 2.5 | 3.5 |
| CaO | Mol % | 8.0 | 8.0 | 8.0 | 8.0 | 4.6 | 9.5 | 10.1 | 8.2 | 7.2 |
| SrO | Mol % | 5.0 | 5.0 | 5.0 | 5.0 | 5.2 | 5.0 | 5.0 | 0.8 | 0.8 |
| BaO | Mol % | 2.0 | 2.0 | 2.0 | 2.0 | 0.0 | 2.0 | 2.0 | 0.0 | 0.0 |
| MgO + CaO | Mol % | 20.0 | 20.0 | 20.0 | 20.0 | 9.7 | 24.0 | 25.2 | 10.7 | 10.7 |
| R₂O (MgO + CaO + SrO + BaO) | Mol % | 27.0 | 27.0 | 27.0 | 27.0 | 14.9 | 31.0 | 32.2 | 11.5 | 11.5 |
| MgO/(CaO + MgO) | — | 0.60 | 0.60 | 0.60 | 0.60 | 0.53 | 0.60 | 0.60 | 0.23 | 0.33 |
| CaO/SiO₂ | — | 0.13 | 0.13 | 0.13 | 0.13 | 0.07 | 0.15 | 0.16 | 0.12 | 0.11 |
| SrO/(MgO + CaO) | — | 0.25 | 0.25 | 0.25 | 0.25 | 0.54 | 0.21 | 0.20 | 0.07 | 0.07 |
| BaO/(MgO + CaO) | — | 0.10 | 0.10 | 0.10 | 0.10 | 0.00 | 0.08 | 0.08 | 0.00 | 0.00 |
| (BaO + SrO)/(MgO + CaO) | — | 0.35 | 0.35 | 0.35 | 0.35 | 0.54 | 0.29 | 0.28 | 0.07 | 0.07 |
| Al₂O₃/R²O | — | 0.31 | 0.43 | 0.31 | 0.31 | 0.76 | 0.11 | 0.05 | 1.04 | 1.04 |
| Y₂O₃ | Mol % | 0.0 | 0.0 | 0.0 | 0.0 | 0.0 | 0.0 | 0.0 | 0.0 | 0.0 |
| Li₂O | Mol % | 0.0 | 0.0 | 0.0 | 0.0 | 0.0 | 0.0 | 0.0 | 0.0 | 0.0 |
| Na₂O | Mol % | 1.0 | 1.0 | 1.0 | 4.0 | 0.0 | 1.0 | 1.0 | 0.0 | 0.0 |
| K₂O | Mol % | 0.3 | 0.3 | 0.3 | 0.3 | 0.0 | 0.3 | 0.3 | 0.0 | 0.0 |
| R¹₂O (Li₂O + Na₂O + K₂O) | Mol % | 1.3 | 1.3 | 1.3 | 4.3 | 0.0 | 1.3 | 1.3 | 0.0 | 0.0 |
| ZnO | Mol % | 0.0 | 0.0 | 0.0 | 0.0 | 0.0 | 0.0 | 0.0 | 0.0 | 0.0 |
| ZrO₂ | Mol % | 0.2 | 0.2 | 0.2 | 0.2 | 0.0 | 0.2 | 0.2 | 0.0 | 0.0 |
| Impurity element (in terms of oxide) | Mol % | 0.0 | 0.0 | 0.0 | 0.0 | 0.0 | 0.0 | 0.0 | 0.0 | 0.0 |
| Si | Mol % | 0.0 | 0.0 | 0.0 | 0.0 | 0.0 | 0.0 | 0.0 | 0.0 | 0.0 |
| F | Mass % | 1.2 | 0.15 | 0.15 | 0.15 | 0.0 | 0.15 | 0.15 | 0.0 | 0.0 |
| Expansion coefficient | ppm/° C. | 5.5 | 5.3 | 5.3 | 5.3 | 3.8 | 5.7 | 5.8 | 3.3 | 3.3 |
| Visible light transmittance | % | 90% or | 90% or | 90% or | 90% or | 90% or | 90% or | 90% or | 90% or | 90% or |
| | | more | more | more | more | more | more | more | more | more |
| T₂ (logη = 2) | ° C. | 1515 | 1470 | 1368 | 1362 | 1645 | 1606 | 1630 | 1657 | 1658 |
| Manufacturing characteristics | — | B | A | A | A | A | B | B | A | A |
| Etching amount | nm | 541 | 547 | 601 | 566 | 890 | 476 | 450 | 592 | 627 |
| Presence or absence of | — | A | A | A | A | A | A | A | A | A |
| heterogeneous phase | | | | | | | | | | |
| Processability | — | A | A | A | A | A | A | A | A | A |

TABLE 3

| | | Ex. 19 | Ex. 20 | Ex. 21 | Ex. 22 | Ex. 23 | Ex. 24 | Ex. 25 | Ex. 26 | Ex. 27 |
|---|---|---|---|---|---|---|---|---|---|---|
| SiO₂ | Mol % | 61.6 | 61.6 | 61.6 | 61.6 | 61.6 | 57.3 | 65.1 | 60.0 | 60.0 |
| B₂O₃ | Mol % | 0.0 | 0.0 | 0.0 | 0.0 | 0.0 | 12.0 | 8.0 | 8.0 | 8.0 |
| P₂O₅ | Mol % | 0.0 | 0.0 | 0.0 | 0.0 | 0.0 | 0.0 | 0.0 | 0.0 | 0.0 |
| a (SiO₂ + B₂O₃ + P₂O₅) | Mol % | 61.6 | 61.6 | 61.6 | 61.6 | 61.6 | 69.3 | 73.1 | 68.0 | 68.0 |
| Al₂O₃ | Mol % | 12.1 | 12.1 | 12.1 | 12.1 | 12.1 | 6.5 | 1.6 | 9.0 | 9.0 |
| Ga₂O₃ | Mol % | 0.0 | 0.0 | 0.0 | 0.0 | 0.0 | 0.0 | 0.0 | 0.0 | 0.0 |
| MgO | Mol % | 11.5 | 10.1 | 8.6 | 7.1 | 0.0 | 4.7 | 3.5 | 7.0 | 7.0 |
| CaO | Mol % | 14.8 | 16.2 | 17.7 | 19.2 | 26.3 | 18.2 | 20.8 | 15.0 | 12.0 |
| SrO | Mol % | 0.0 | 0.0 | 0.0 | 0.0 | 0.0 | 1.1 | 1.0 | 1.0 | 4.0 |
| BaO | Mol % | 0.0 | 0.0 | 0.0 | 0.0 | 0.0 | 0.2 | 0.0 | 0.0 | 0.0 |
| MgO + CaO | Mol % | 26.3 | 26.3 | 26.3 | 26.3 | 26.3 | 22.9 | 24.3 | 22.0 | 19.0 |
| R₂O (MgO + CaO + SrO + BaO) | Mol % | 26.3 | 26.3 | 26.3 | 26.3 | 26.3 | 24.2 | 25.3 | 23.0 | 23.0 |
| MgO/(CaO + MgO) | — | 0.44 | 0.38 | 0.33 | 0.27 | 0.00 | 0.21 | 0.14 | 0.32 | 0.37 |
| CaO/SiO₂ | — | 0.24 | 0.26 | 0.29 | 0.31 | 0.43 | 0.32 | 0.32 | 0.25 | 0.20 |
| SrO/(MgO + CaO) | — | 0.00 | 0.00 | 0.00 | 0.00 | 0.00 | 0.05 | 0.04 | 0.05 | 0.21 |
| BaO/(MgO + CaO) | — | 0.00 | 0.00 | 0.00 | 0.00 | 0.00 | 0.01 | 0.00 | 0.00 | 0.00 |
| (BaO + SrO)/(MgO + CaO) | — | 0.00 | 0.00 | 0.00 | 0.00 | 0.00 | 0.06 | 0.04 | 0.05 | 0.21 |
| Al₂O₃/R²O | — | 0.46 | 0.46 | 0.46 | 0.46 | 0.46 | 0.27 | 0.06 | 0.39 | 0.39 |
| Y₂O₃ | Mol % | 0.0 | 0.0 | 0.0 | 0.0 | 0.0 | 0.0 | 0.0 | 0.0 | 0.0 |
| Li₂O | Mol % | 0.0 | 0.0 | 0.0 | 0.0 | 0.0 | 0.0 | 0.0 | 0.0 | 0.0 |
| Na₂O | Mol % | 0.0 | 0.0 | 0.0 | 0.0 | 0.0 | 0.0 | 0.0 | 0.0 | 0.0 |
| K₂O | Mol % | 0.0 | 0.0 | 0.0 | 0.0 | 0.0 | 0.0 | 0.0 | 0.0 | 0.0 |
| R¹₂O (Li₂O + Na₂O + K₂O) | Mol % | 0.0 | 0.0 | 0.0 | 0.0 | 0.0 | 0.0 | 0.0 | 0.0 | 0.0 |
| ZnO | Mol % | 0.0 | 0.0 | 0.0 | 0.0 | 0.0 | 0.0 | 0.0 | 0.0 | 0.0 |
| ZrO₂ | Mol % | 0.0 | 0.0 | 0.0 | 0.0 | 0.0 | 0.0 | 0.0 | 0.0 | 0.0 |
| Impurity element (in terms of oxide) | Mol % | 0.0 | 0.0 | 0.0 | 0.0 | 0.0 | 0.0 | 0.0 | 0.0 | 0.0 |
| Si | Mol % | 0.0 | 0.0 | 0.0 | 0.0 | 0.0 | 0.0 | 0.0 | 0.0 | 0.0 |
| F | Mass % | 0.0 | 0.0 | 0.0 | 0.0 | 0.0 | 0.0 | 0.0 | 0.0 | 0.0 |
| Expansion coefficient | ppm/° C. | 4.6 | 4.6 | 4.7 | 5.0 | 5.3 | 4.7 | 4.7 | 4.6 | 4.5 |
| Visible light transmittance | % | 90% | 90% | 90% | 90% | 70% | 60% | 60% | 90% | 90% |
| | | or more | or more | or more | or more | or more | or more | or more | or more | or more |
| T₂ (logη = 2) | ° C. | 1519 | 1515 | 1513 | 1505 | Not | Not | Not | Not | Not |
| | | | | | | measured | measured | measured | measured | measured |
| Manufacturing characteristics | — | A | A | A | A | B | B | B | A | A |
| Etching amount | nm | 388 | 365 | 351 | 327 | 341 | 356 | 351 | 342 | 350 |
| Presence or absence of | — | A | A | A | A | B | B | B | A | A |
| heterogeneous phase | | | | | | | | | | |
| Processability | — | A | A | A | A | B | A | A | A | A |

TABLE 4

| | | Ex. 28 | Ex. 29 | Ex. 30 | Ex. 31 | Ex. 32 | Ex. 33 | Ex. 34 | Ex. 35 |
|---|---|---|---|---|---|---|---|---|---|
| SiO₂ | Mol % | 58.6 | 57.6 | 58.6 | 57.6 | 61.2 | 59.9 | 60.6 | 60.6 |
| B₂O₃ | Mol % | 0.0 | 0.0 | 0.0 | 0.0 | 0.4 | 1.7 | 0.0 | 0.0 |
| P₂O₅ | Mol % | 3.0 | 6.0 | 0.0 | 0.0 | 0.0 | 0.0 | 0.0 | 0.0 |
| a (SiO₂ + B₂O₃ + P₂O₅) | Mol % | 61.6 | 63.6 | 58.6 | 57.6 | 61.6 | 61.6 | 60.6 | 60.6 |
| Al₂O₃ | Mol % | 12.1 | 11.1 | 12.1 | 11.1 | 12.1 | 12.1 | 12.1 | 11.1 |
| Ga₂O₃ | Mol % | 0.0 | 0.0 | 0.0 | 0.0 | 0.0 | 0.0 | 0.0 | 0.0 |
| MgO | Mol % | 15.3 | 14.3 | 15.3 | 14.3 | 15.3 | 15.3 | 14.3 | 14.8 |
| CaO | Mol % | 11.0 | 11.0 | 11.0 | 11.0 | 11.0 | 11.0 | 10.0 | 10.5 |
| SrO | Mol % | 0.0 | 0.0 | 0.0 | 0.0 | 0.0 | 0.0 | 0.0 | 0.0 |
| BaO | Mol % | 0.0 | 0.0 | 0.0 | 0.0 | 0.0 | 0.0 | 0.0 | 0.0 |
| MgO + CaO | Mol % | 26.3 | 25.3 | 26.3 | 25.3 | 26.3 | 26.3 | 24.3 | 25.3 |
| R₂O (MgO + CaO + SrO + BaO) | Mol % | 26.3 | 25.3 | 26.3 | 25.3 | 26.3 | 26.3 | 24.3 | 25.3 |
| MgO/(CaO + MgO) | — | 0.58 | 0.57 | 0.58 | 0.57 | 0.58 | 0.58 | 0.59 | 0.58 |
| CaO/SiO₂ | — | 0.19 | 0.19 | 0.19 | 0.19 | 0.18 | 0.18 | 0.17 | 0.17 |
| SrO/(MgO + CaO) | — | 0.00 | 0.00 | 0.00 | 0.00 | 0.00 | 0.00 | 0.00 | 0.00 |
| BaO/(MgO + CaO) | — | 0.00 | 0.00 | 0.00 | 0.00 | 0.00 | 0.00 | 0.00 | 0.00 |
| (BaO + SrO)/(MgO + CaO) | — | 0.00 | 0.00 | 0.00 | 0.00 | 0.00 | 0.00 | 0.00 | 0.00 |
| Al₂O₃/R²O | — | 0.46 | 0.44 | 0.46 | 0.44 | 0.46 | 0.46 | 0.50 | 0.44 |
| Y₂O₃ | Mol % | 0.0 | 0.0 | 0.0 | 0.0 | 0.0 | 0.0 | 0.0 | 3.0 |
| Li₂O | Mol % | 0.0 | 0.0 | 0.0 | 0.0 | 0.0 | 0.0 | 0.0 | 0.0 |
| Na₂O | Mol % | 0.0 | 0.0 | 0.0 | 0.0 | 0.0 | 0.0 | 0.0 | 0.0 |
| K₂O | Mol % | 0.0 | 0.0 | 0.0 | 0.0 | 0.0 | 0.0 | 0.0 | 0.0 |
| R¹₂O (Li₂O + Na₂O + K₂O) | Mol % | 0.0 | 0.0 | 0.0 | 0.0 | 0.0 | 0.0 | 0.0 | 0.0 |
| ZnO | Mol % | 0.0 | 0.0 | 3.0 | 6.0 | 0.0 | 0.0 | 0.0 | 0.0 |
| ZrO₂ | Mol % | 0.0 | 0.0 | 0.0 | 0.0 | 0.0 | 0.0 | 0.0 | 0.0 |
| Impurity element (in terms of oxide) | Mol % | 0.0 | 0.0 | 0.0 | 0.0 | 0.0 | 0.0 | 3.0 | 0.0 |
| Si | Mol % | 0.0 | 0.0 | 0.0 | 0.0 | 0.0 | 0.0 | 0.0 | 0.0 |
| F | Mass % | 0.0 | 0.0 | 0.0 | 0.0 | 0.0 | 0.0 | 0.0 | 0.0 |
| Expansion coefficient | ppm/° C. | Not | Not | Not | Not | 4.5 | 4.5 | 4.6 | 4.7 |
| | | measured | measured | measured | measured | | | | |
| Visible light transmittance | % | 90% | 90% | 90% | 90% | 90% | 90% | 60% | 90% |
| | | or more | or more | or more | or more | or more | or more | or more | or more |
| T₂ (logη = 2) | ° C. | Not | Not | Not | Not | 1485 | 1442 | 1533 | Not |
| | | measured | measured | measured | measured | | | | measured |
| Manufacturing characteristics | — | A | A | A | A | A | A | A | A |
| Etching amount | nm | 469 | 490 | 461 | 485 | 430 | 445 | 463 | 397 |
| Presence or absence of | — | A | A | A | A | A | A | B | A |
| heterogeneous phase | | | | | | | | | |
| Processability | — | A | A | A | A | A | A | A | A |

TABLE 5

| | | Ex. 36 | Ex. 37 | Ex. 38 | Ex. 39 | Ex. 40 | Ex. 41 |
|---|---|---|---|---|---|---|---|
| SiO₂ | Mol % | 50.0 | 53.0 | 100.0 | 56.0 | 62.0 | 0.0 |
| B₂O₃ | Mol % | 0.0 | 4.0 | 0.0 | 28.0 | 31.0 | 0.0 |
| P₂O₅ | Mol % | 0.0 | 0.0 | 0.0 | 0.0 | 0.0 | 0.0 |
| a (SiO₂ + B₂O₃ + P₂O₅) | Mol % | 50.0 | 57.0 | 100.0 | 84.0 | 93.0 | 0.0 |
| Al₂O₃ | Mol % | 0.0 | 0.0 | 0.0 | 2.0 | 4.6 | 0.0 |
| Ga₂O₃ | Mol % | 0.0 | 0.0 | 0.0 | 0.0 | 0.0 | 0.0 |
| MgO | Mol % | 18.0 | 14.0 | 0.0 | 3.2 | 0.0 | 0.0 |
| CaO | Mol % | 29.0 | 23.0 | 0.0 | 0.0 | 0.0 | 0.0 |
| SrO | Mol % | 0.0 | 5.0 | 0.0 | 0.8 | 2.0 | 0.0 |
| BaO | Mol % | 0.0 | 1.0 | 0.0 | 0.2 | 0.4 | 0.0 |
| MgO + CaO | Mol % | 47.0 | 37.0 | 0.0 | 3.2 | 0.0 | 0.0 |
| R₂O (MgO + CaO + SrO + BaO) | Mol % | 47.0 | 43.0 | 0.0 | 4.2 | 2.4 | 0.0 |
| MgO/(CaO + MgO) | — | 0.38 | 0.38 | — | 1.00 | — | — |
| CaO/SiO₂ | — | 0.58 | 0.43 | 0.00 | 0.00 | 0.00 | — |
| SrO/(MgO + CaO) | — | 0.00 | 0.14 | — | 0.25 | — | — |
| BaO/(MgO + CaO) | — | 0.00 | 0.03 | — | 0.06 | — | — |
| (BaO + SrO)/(MgO + CaO) | — | 0.00 | 0.16 | — | 0.31 | — | — |
| Al₂O₃/R²O | — | 0.00 | 0.00 | — | 0.48 | 1.92 | — |
| Y₂O₃ | Mol % | 0.0 | 0.0 | 0.0 | 0.0 | 0.0 | 0.0 |
| Li₂O | Mol % | 0.0 | 0.0 | 0.0 | 0.0 | 0.0 | 0.0 |
| Na₂O | Mol % | 0.0 | 0.0 | 0.0 | 9.8 | 0.0 | 0.0 |
| K₂O | Mol % | 0.0 | 0.0 | 0.0 | 0.0 | 0.0 | 0.0 |
| R¹₂O (Li₂O + Na₂O + K₂O) | Mol % | 0.0 | 0.0 | 0.0 | 9.8 | 0.0 | 0.0 |
| ZnO | Mol % | 0.0 | 0.0 | 0.0 | 0.0 | 0.0 | 0.0 |
| ZrO₂ | Mol % | 0.0 | 0.0 | 0.0 | 0.0 | 0.0 | 0.0 |
| Impurity element (in terms of oxide) | Mol % | 0.0 | 0.0 | 0.0 | 0.0 | 0.0 | 0.0 |
| Si | Mol % | 3.0 | 0.0 | 0.0 | 0.0 | 0.0 | 100.0 |
| F | Mass % | 0.0 | 0.0 | 0.0 | 0.0 | 0.0 | 0.0 |
| Expansion coefficient | ppm/° C. | 8.0 | 7.4 | 0.6 | Not | Not | Not |
| | | | | | measured | measured | measured |
| Visible light transmittance | % | 90% or | 90% or | 90% or | 90% or | 90% or | Less than |
| | | more | more | more | more | more | 60% |
| T₂ (logη = 2) | ° C. | 1305 | 1311 | Not | Not | Not | — |
| | | | | measured | measured | measured | |
| Manufacturing characteristics | — | B | B | A | A | A | A |
| Etching amount | nm | 301 | 382 | 9987 | 4112 | 5032 | 16211 |
| Presence or absence of heterogeneous phase | — | C | A | A | A | A | A |
| Processability | — | C | C | A | A | A | A |

### <Conclusion of Evaluation Results>

As shown in Tables 1 to 5 described above, the glass block in Examples 1 to 35 have excellent plasma resistance and mechanical strength.

On the other hand, in the glass blocks in Examples 36 to 41, at least one of the plasma resistance and the mechanical strength is insufficient.

Although the embodiments of the present invention have been described above, the embodiment is not limited to the contents of these embodiments. In addition, the components described above should include those that can be easily conceived by a person skilled in the art, those that are substantially the same, and those within a so-called equivalent scope. Further, the above components can be appropriately combined. Further, various omissions, substitutions, or modifications of the components can be made without departing from the gist of the embodiment described above.

The present application is based on a Japanese Patent Application (Japanese Patent Application No. 2022-060326) filed on Mar. 31, 2022, and the contents thereof are incorporated herein by reference.

1. A glass block for a plasma resistant member, comprising silicon and at least one of magnesium and calcium,
wherein, in terms of mole percentage based on an oxide,
a total content of MgO and CaO is 3.0 mol % or more and less than 29.0 mol %,
a content of R²O is 3.0 mol % or more and less than 35.0 mol %, and
a content of R¹₂O is 8.0 mol % or less,
provided that R¹ is an alkali metal element and R² is an alkaline earth metal element.

2. The glass block according to claim 1, wherein
a content of SiO₂ is 40.0 mol % or more and less than 90.0 mol %, and
a content of B₂O₃ is less than 30.0 mol %.

3. The glass block according to claim 1, wherein
a ratio of a content of SrO to the total content of MgO and CaO is less than 0.50, and
the content of SrO is less than 15.0 mol %.

4. The glass block according to claim 1, wherein
a ratio of a total content of BaO and SrO to the total content of MgO and CaO is less than 0.45.

5. The glass block according to claim 1, wherein
a ratio of a content of BaO to the total content of MgO and CaO is less than 0.35.

6. The glass block according to claim 1, having an average thermal expansion coefficient at 50° C. to 350° C. of 5.0 ppm/° C. or less.

7. The glass block according to claim 1, wherein
a ratio of a content of Al₂O₃ to the content of R²O is less than 0.6, and
the content of Al₂O₃ is less than 20.0 mol %.

8. The glass block according to claim 1, wherein
a content of fluorine is 5.0 mass % or less with respect to a total mass of the glass block.

9. The glass block according to claim 1, having a visible light transmittance of 60% or more.

10. The glass block according to claim 1, wherein
a ratio of a content of MgO to the total content of MgO and CaO is 0.1 to 0.9.

11. The glass block according to claim 1, wherein
a content of P₂O₅ is 0.1 mol % or more and less than 5.5 mol %.

12. The glass block according to claim 1, wherein
the content of R²O is 3.0 mol % or more and less than 20.0 mol %.

13. A method for manufacturing the glass block according to claim 1, the method comprising:
melting a glass raw material by heating at 1650° C. or less; and
molding and annealing an obtained molten glass.

14. A plasma resistant member comprising the glass block according to claim 1.

15. The plasma resistant member according to claim 14, wherein
the plasma resistant member is to be mounted on a plasma etching apparatus, and is a window material, a top plate, a microwave introduction tube, a lift pin, a nozzle, an edge ring, an electrostatic chuck, a shower plate, or a protective cover for a sensor inside a chamber.
